(19) United States
(12) Patent Application Publication
(10) Pub. No.: US 2009/0087965 A1
(43) Pub. Date: Apr. 2, 2009

(54) STRUCTURE AND METHOD FOR MANUFACTURING PHASE CHANGE MEMORIES

(75) Inventors: Cay-Uwe Pinnow, Berlin (DE); Thomas Happ, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Munich (DE)

(21) Appl. No.: 12/196,820

(22) Filed: Aug. 22, 2008

Related U.S. Application Data
(62) Division of application No. 11/174,894, filed on Jul. 5, 2005.

(51) Int. Cl. H01L 21/20

(52) U.S. Cl. 438/483; 257/E21.09

(57) ABSTRACT

A method for manufacturing at least one resistively switching memory cell including generating a first electrode; depositing a phase change material layer, the phase change material layer including a composition of formula GaₓGe_{y}In_{z}Sb_{1-x-y-z} that also incorporates at least elemental oxygen or elemental nitrogen, where x, y, and z are each between 0 and 1 and the sum of x, y, and z is less than or equal to 1; and generating a second electrode, the phase change material layer in working relation with the first electrode and with the second electrode.

### CROSS-REFERENCE TO RELATED APPLICATIONS

This Utility Patent Application is a Divisional of U.S. patent application Ser. No. 11/174,894, filed Jul. 5, 2005, entitled: Structure and Method for Manufacturing Phase Change Memories with Particular Switching Characteristics, which is hereby incorporated herein in its entirety.

### BACKGROUND

The present invention relates to a method for manufacturing a phase change memory and a memory device having at least one phase change memory cell.

As possible alternatives to the hitherto common semiconductor memories such as DRAM, SRAM, or FLASH, so-called “resistive” or “resistively switching” memory devices, in particular phase change memories (PCM) have been known. In the case of phase change memories, an “active” or else “switching active” material or a phase change medium, respectively, is positioned between two electrodes (e.g. an anode and a cathode), e.g. a material with an appropriate chalcogenide compound (e.g. a Ge—Sb—Te or an Ag—In—Sb—Te compound) which is characterized by resistive switchability.

In a phase change memory cell, the phase change material is adapted to be placed, by appropriate switching processes, in an amorphous, relatively weakly conductive state, or in a crystalline, relatively strongly conductive state. In order to achieve, with a resistively switching phase change memory cell, a change from an amorphous state with a relatively weak electrical conductivity of the switching active material to a crystalline state with a relatively good electrical conductivity of the switching active material, an appropriate heating current pulse or heating voltage pulse, respectively, can be applied to the electrodes, said heating current pulse or heating voltage pulse, respectively, leading to the switching active material being heated beyond the crystallization temperature and crystallizing (writing process or SET process, respectively).

Vice versa, a change of state of the switching active material from a crystalline, i.e. relatively strongly conductive state, to an amorphous, i.e. relatively weakly conductive state, may, for instance, be achieved by—again by means of an appropriate heating current pulse or heating voltage pulse, respectively—the switching active material being heated beyond the melting temperature and being subsequently “quenched” to an amorphous state by quick cooling (deleting process or RESET process, respectively).

The functioning of phase change memories is consequently based on the amorphous-crystalline phase transition of a phase change material, wherein the two states of a phase change memory cell, namely the amorphous, high-resistance state and the crystalline, low-resistance state, respectively, together represent one bit, i.e. a logic “1” or a logic “0”. Here, use is made of the effect that the two phases of these compounds differ distinctly in their electrical conductivity and that the state of the phase change memory cell can thus be recognized again or be read out, respectively.

The programming (writing process or SET process, respectively) of a memory cell that is in the amorphous, high-resistance state to the low-resistance, crystalline phase is performed in that the material of the phase change memory is heated beyond the crystallization temperature by an electrical heating pulse and is thus crystallized. The reverse procedure, i.e. the deleting process or RESET process, respectively, is performed in that the material is heated beyond the melting point of the phase change material with a stronger heating pulse, i.e. with a higher power input than with the writing process or SET process, respectively, and is subsequently quenched in the amorphous, high-resistance state by quick cooling.

The information content of the memory cell is read out in that a lower reading voltage is applied to the cell, wherein the current I_{read} through the cell resulting from the reading voltage applied is substantially lower than the programming current Iₛₑₜ and the deleting current Iᵣₑₛₑₜ. This may also be represented by the following equation of relationship:

I_{read}<<Iₛₑₜ<Iᵣₑₛₑₜ

The difference in selecting the optimum material for the active phase change medium results from the contrary demands for a melting point that is as low as possible, so as to achieve a low power consumption or current requirement with the RESET process, i.e. with the conversion from the crystalline state to the amorphous state, and from the simultaneous demand for a high crystallization temperature, so as to achieve long data storage times (in the amorphous state) at higher operating temperatures.

In order to enable a quick memory operation, a high crystallization rate is required. Due to the incomplete phase transition that typically exists in electrical phase change memories (e-PCM), it is in particular phase change materials with a high crystal growth rate, so-called “fast-growth materials”, vis-à-vis “fast nucleation materials”, such as a Ge—Sb—Te compound (in short: GST) of germanium (Ge), antimony (Sb) and tellurium (Te) that are especially well suited.

So far, primarily GeSbTe-based phase change materials have been used for electrical phase change memories. They do, however, not possess the optimum material parameters for the successful construction of a universal memory, i.e. quick data access, utmost “cycle strength”, and non-volatile data storage, with the requirement being a data storage time of 10 years at 120° C. Some industrial applications, e.g. in the automotive field, even require a 10-year data storage time at 150° C. This specification can presumably not be achieved with Ge—Sb—Te compounds.

The only known investigations with respect to alternative material classes for electrical phase change memories have so far been restricted to the quaternary (AgIn)SbTe material system with silver (Ag), indium (In), antimony (Sb), and tellurium (Te), or to the SeSbTe material system with selenium (Se), antimony (Sb), and tellurium (Te), respectively. The (AgIn)SbTe material system as a quaternary material is substantially more difficult to master during the manufacturing than are binary or ternary systems. SeSbTe material systems cannot do justice to the requirements for data storage at higher temperatures. Thus, data storage times of no more than minutes to hours can be achieved at a temperature of 80° C.

For these and other reasons, there is a need for the present invention.

### BRIEF DESCRIPTION OF THE DRAWINGS

FIG. 1 is a schematic view of one embodiment of a phase change memory of the present invention.

FIG. 2 is a schematic view of one embodiment of a method of producing a phase change memory cell of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., may be used with reference to the orientation of the Figure(s) being described. Because components of embodiments of the present invention can be positioned in a number of different orientations, any directional terminology is used for purposes of illustration and is in no way limiting. It is to be understood that embodiments in addition those disclosed herein may be utilized and that structural or logical changes may be made without departing from the scope of the present invention. The following detailed description, therefore, is not to be taken in a limiting sense, and the scope of the present invention is defined by the appended claims.

The present invention relates to a method for manufacturing a phase change memory and a memory device having at least one phase change memory cell. In one embodiment of the present invention, a phase change memory includes at least one phase change memory cell having:
at least one phase change material layer with a switching active material compound contacted by at least
   a first electrode adjacent to the switching active phase change material layer, and
   a second electrode adjacent to the switching active phase change material layer at some other position,
whereby the phase change material layer includes a material compound with the chemical composition GaₓGe_{y}In_{z}Sb_{1-x-y-z} and is charged or mixed with oxygen and/or with nitrogen.

In another aspect, the present invention provides a method for manufacturing a phase change memory, such as a phase change material in which contrary requirements for the phase change material are better harmonized. For example, a method for manufacturing a phase change memory that includes at least one resistively switching memory cell, such as a phase change memory cell, may entail:
generating a first electrode;
depositing a phase change material layer with a switching active material compound with the chemical composition GaₓGe_{y}In_{z}Sb_{1-x-y-z}; and
generating a second electrode; wherein the phase change material layer is doped with nitrogen (N₂) or oxygen (O₂).
   The indices x, y, and z each stand for a value between 0 and 1 and thus indicate the proportion of the corresponding component in the material compound. For instance, the chemical composition of a material compound with regular atomic % proportions of all components Ga, Ge, In and Sb would be represented by Ga_{0.25}Ge_{0.25}In_{0.25}Sb_{0.25}. Furthermore, one or two component(s) of the materials Ga, Ge, or In may be missing in the material compound, so the index value of the respective component is Zero.

The doping of a GaₓGe_{y}In_{z}Sb_{1-x-y-z} material compound with nitrogen or oxygen according to the inventive method results, for instance, in material compounds with the chemical composition GaSb—N or GaSb—O. When used as an active phase change material in an electrical phase change memory cell, these compounds offer a distinct improvement vis-à-vis the hitherto used standard materials with respect to the power requirement of the phase change memory, the writing rate, and the data storage at increased temperatures.

Another advantage of the inventive method consists in the specific resistance of the Ga—Sb basic material can, by the addition of nitrogen and/or oxygen to the phase change material layer, be increased by the gradual addition of nitrogen or oxygen, respectively. This further entails the advantage that the material for the deleting current pulse or RESET pulse, respectively, requires lower currents to be heated to the melting temperature since the voltage drop is higher. This way, the deleting current can be strongly reduced, so that it may be supplied by a transistor with lower channel width whereby the cell size may be reduced.

By the inventive method, it is further possible to suppress the metal diffusion of electrode material in the phase change material since the diffusion paths are strongly reduced along grain boundaries in the nano-crystalline structure of the phase change material layer. Another particular advantage of the inventive method consists in that the course of doping may be continuously varied within the phase change material layer. By that it is, for instance, also possible to produce a selectively doped interface to the first electrode of the phase change memory cell in that the doping of the phase change material layer is e.g. reduced continuously towards the centre of the layer and is subsequently increased again towards the boundary region of the phase change material layer to the second electrode.

An important quantity for describing the characteristics of resistively switching material compounds is the eutectic point. If a metal A is dissolved in a metal B, the melting point of he metal B will first of all decrease to the eutectic point where the melting point increases again and approaches, with an increasing content of the metal A in the mixture, the melting point of the metal A. The alloy that is generated by the solidifying of the mixture at the eutectic point is also referred to as eutectic mixture.

The eutectic point designates a temperature at which a heterogeneous mixed phase, e.g. a eutectic metal alloy, passes over directly from the solid to the liquid phase without a further phase state occurring. With eutectic metal alloys of two or three components, this temperature depends on the composition thereof. The melting point of eutectic alloys lies distinctly below the melting point of pure metals, so that such alloys are especially well suited to be used as phase change materials.

With a metal compound consisting of two metals, a eutectic point only exists with exactly defined quantity ratios between the two metals. The material compound GaSb with an element composition of Ga_{0.116}Sb_{0.884} or Ga_{11.6}Sb_{88.4}, respectively, i.e. 11.6 at. % gallium (Ga) and 88.4 at. % antimony (Sb) has, in the binary phase diagram, in the vicinity of the eutectic point a lower melting temperature of approx. 589° C. than the compound of the GST reference system Ge₂Sb₂Te₅.

Due to the lower melting temperature of the novel phase change materials, the heating power required for melting the material during the RESET process is reduced. At the same time, the crystallization temperature is distinctly higher with the composition Ga_{11.6}Sb_{88.4} (by approx. 195° C.) than with the standard material GST, which enables correspondingly higher storing and operating temperatures of the phase change memory without the risk of losing a bit stored in the amorphous state of the phase change memory cell.

This effect is also a decisive aspect with respect to the scaling since, with increasing miniaturization, the thermal cross-erase between adjacent memory cells and the undesired heating of the adjacent cell related therewith might be a limiting factor for the miniaturization and stability of the amorphous state in the disturbed memory cell.

The elements of the phase change material in the particular composition as suggested in accordance with the present invention offer, vis-à-vis the hitherto used GST reference system, the advantages of a far better storage of the information stored in the memory cells, and a lower power requirement during the operation of the phase change memory. Moreover, due to reduced RESET currents, the trigger currents may be reduced and thus the cell sizes may be decreased.

The writing rate of a phase change memory is determined by the crystallization time of the amorphous state and is, in the case of the eutectic GaSb, also distinctly less than in the case of the GST reference system. In optical experiments, crystallization rates of up to 23 m/s could be measured. This means that an amorphous region with an extension of 70 nm would crystallize in 3 ns. The comparative value in the GST reference system lies with 35 ns. In order to achieve even higher crystallization temperatures, germanium (Ge) may also be alloyed in addition to generate ternary (Ga,Ge)Sb or quaternary compounds (Ga,Ge)Sb:N or (Ga,Ge)Sb:O, respectively, wherein the expression :N means a doping of the respective compound with nitrogen and the expression :O means a doping of the compound with oxygen.

Commonly, phase change memories as well as other kinds of memory and semiconductor devices are structured with small scaling on a substrate by a number of process steps. A known method for depositing thin material layers in particular of compounds with a plurality of components is magnetron sputtering in a sputtering chamber.

The present invention utilizes this method in one embodiment in that the phase change material of the phase change memory is deposited by reactive magnetron sputtering by the addition of additional gases. Thus, the inventive method offers the possibility of controlling the layer doping of the phase change material layer of the phase change memory cell by means of reactive addition of a suitable nitrogen- or oxygen-containing process gas. This advantage results from the fact that the partial gas pressure of the additional gases can be adjusted exactly by means of a gas flow regulating device.

For manufacturing a phase change memory, the inventive method makes use of a GaₓSb₁₋ₓ target as a material compound sputtering target. In an alternative embodiment of the present method, joint co-sputtering of two targets, e.g. of GaN and GaₓSb₁₋ₓ, or two targets of Ga_{0.5}Sb_{0.5} or Ga₅₀Sb₅₀, respectively, and Sb, or with two targets of GaN and Sb, or with two targets of GaN and SbN, or with two targets of GaSb and Sb—N, may be performed. Argon (Ar) or some other inert gas such as He, Ne, Kr, or Xe, or mixtures of the inert gases mentioned may be used as a working gas. By the addition of a suitable reactive sputtering gas such as N₂, O₂, NH₃, H₂O, N₂O, NO, or O₃, in addition to the working gas, the layer growth of the phase change material layer in the reactive gas-containing atmosphere is influenced and may be described by the following chemical reaction equations:

Reactive Sputtering of the GaSb Target with Nitriding:

GaₓSb₁₋ₓ(s)+N₂(g)+Ar(g)=>GaₓSb₁₋ₓ:N(s)+Ar(g)

Reactive Sputtering of the GaSb Target with Oxidation:

GaₓSb₁₋ₓ(s)+O(g)+Ar(g)=>GaₓSb₁₋ₓ:O(s)+Ar(g)

Simultaneous Oxidation and Nitriding:

GaₓSb₁₋ₓ(s)+N₂(g)+O₂(g)+Ar(g)=>GaₓSb₁₋ₓ:N:O(s)+Ar(g)

The addition in brackets (s) in the reaction equations designates a solid aggregate state and the addition in brackets (g) designates a gaseous aggregate state, whereas the colon represents a doping or an alloy of materials such as oxygen and nitrogen as further compound partners. Alternatively, organic oxygen- or nitrogen-containing gases may also be used in the reaction equations instead of the oxygen or the nitrogen.

The processes with the co-sputtering method may be described by the following chemical reaction equations:

Co-Sputtering Method:

GaₓN₁₋ₓ+GaₓSb₁₋ₓ+Ar(g)=>(Ga_{y}Sb_{1-y})_{z}N_{1-z}

GaₓN₁₋ₓ+GaₓSb₁₋ₓ+Ar(g)+N₂=>(Ga_{y}Sb_{1-y})_{z}N_{1-z}

Another kind of oxidation may also take place by the co-sputtering of GaₓSb₁₋ₓ and an oxide, e.g. SiO₂. The nitriding may in analogy be performed by the co-sputtering of GaₓSb₁₋ₓ and a nitride (e.g. Si₃N₄). Here, it is accepted that another foreign element, e.g. Si, is possibly also incorporated into the phase change material. Expediently, the dielectric material (SiO₂, Si₃N₄) is then sputtered by means of high-frequency sputtering (RF sputtering).

In the above-mentioned methods, an inert gas (Ar, Ne, Kr, He, etc.) is used as a working gas for the sputtering process, said gas, however, not being deposited or incorporated significantly in the growing layer of the active phase change material. By a defined partial gas pressure of the reactive gas, e.g. nitrogen (N₂), oxygen (O₂), or some other of the above-mentioned reactive gases, the composition of the deposited GaₓGe_{y}In_{z}Sb_{1-x-y-z} compound can be adapted gradually, so that, with an increasing partial gas pressure of N₂ or O₂, or an increasing reactive gas partial pressure, respectively, an increasing incorporation of nitrogen or oxygen, respectively, into the layer takes place. Expediently, the reactive gas partial pressure lies in a range of few μTorr to approx. 500 mTorr. The reactive gas partial pressure as well as the partial gas pressure of the inert sputtering gas (which may lie in a parameter range of approx. 1 μTorr-500 mTorr) may be adjusted by the sucking power of he system pump at the sputtering chamber and by suitable gas flow regulating devices.

The further sputtering parameters may be adjusted as follows: The substrate temperature, for instance, of approx. 77K (corresponds to liquid N₂) up to approx. 300° C., the coupled sputtering power, for instance, of approx. 50 W to approx. 20 kW, and the bias voltage of the substrate (substrate bias), for instance, of approx. −1000 V to approx. +1000 V. Due to a suitable adjustment of these sputtering parameters, the reactive sputtering process may be optimized and stabilized. Thus, in addition to the homogeneousness of the layer, further layer characteristics such as stoichiometry, density, crystallinity, morphology, adherence to the substrate, etc. may be adjusted and optimized.

Moreover, it may be advantageous to thermally post-treat the layer after the reactive deposition process in a tempering process, e.g. by a furnace process in an inert gas atmosphere, for instance, of N₂ or Ar, where undesired reactive gas components are driven out (e.g. H₂ or Ar contaminations in the GaₓGe_{y}In_{z}Sb_{1-x-y-z} layer), which have possibly been incorporated in the layer by kinetic processes during sputtering. In addition, an advantageous change in the structure and/or the crystallinity of the probe may occur by such tempering process.

Alternatively, the phase change material layer of the phase change memory cell may, instead of the reactive magnetron sputtering, also be deposited by a CVD process (chemical vapor deposition), by a PECVD process (plasma-enhanced chemical vapor deposition), or by a MOCVD process (metal-organic chemical vapor deposition).

In the case of the MOCVD deposition process, the intrinsically occurring conform growth process is in particular of advantage for the complete filling of narrow via holes. The MOCVD deposition process may, for instance, be performed in a medium pressure reactor at approx. 75 Torr by the reaction of trimethylgallium (CH₃)₃Ga with trimethylantimony (CH₃)₃Sb by adding ammonia (NH₃) and H₂ carrier gas at high temperatures of approx. 700 to approx. 1000° C. For a doping with oxygen, e.g. H₂O may be used as an addition instead of ammonia. By the use of an additional RF plasma excitation, for instance by means of PECVD (plasma-enhanced chemical vapor deposition), lower working temperatures may be achieved in the growth chamber. Moreover, the use of other metal-organic compounds containing Ge, Ga, and Sb individually or in combination is also possible.

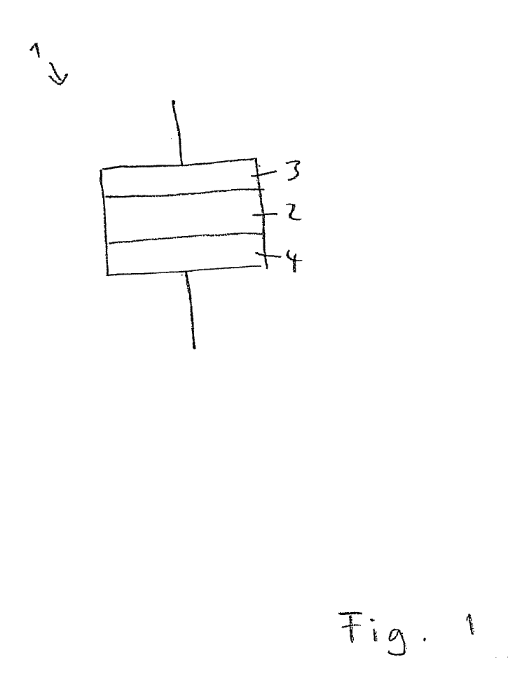

FIG. 1 shows a—purely schematic—representation of a phase change memory according to an exemplary embodiment of the present invention. As can be seen from FIG. 1, the phase change memory includes at least one phase change memory cell 1 with:
at least one switching active phase change material layer 2 contacted by at least
a first electrode 4 adjacent to the switching active phase change material layer 2, and
a second electrode 3 adjacent to the switching active phase change material layer 2 at another position, wherein the phase change material layer 2 contains a material compound with the chemical composition GaₓGe_{y}In_{z}Sb_{1-x-y-z}.

By the use of a material compound with the chemical composition GaₓGe_{y}In_{z}Sb_{1-x-y-z} as a switching active phase change memory material, the present invention makes use of the advantageous characteristics of these material compounds, as described above. In one embodiment of the inventive phase change memory, the active phase change medium substantially consists of binary material compounds with the chemical composition GaSb and/or GaSb which contain, due to a doping or oxidation, respectively, in addition the materials oxygen or nitrogen as further compound partners.

Furthermore, the phase change material layer 2 may contain ternary material compounds with the chemical composition GaSb:N or GaSb:O, respectively. By the use of additional germanium (Ge), quaternary material compounds with the chemical composition (Ga,Ge)Sb:N or (Ga,Ge)Sb:O, respectively, may also be generated in the phase change material layer 2. Moreover, the use of 5-component compounds with the chemical composition (Ga,Ge,In,Sb):N or (Ga,Ge,In,Sb):O, respectively, or (Ga,Ge)In:Sb:N or (Ga,Ge)In:Sb:O, respectively, is also possible in the phase change material layer 2, wherein both antimony (Sb) and oxygen or nitrogen, respectively, may be added to the material compound in a doping process.

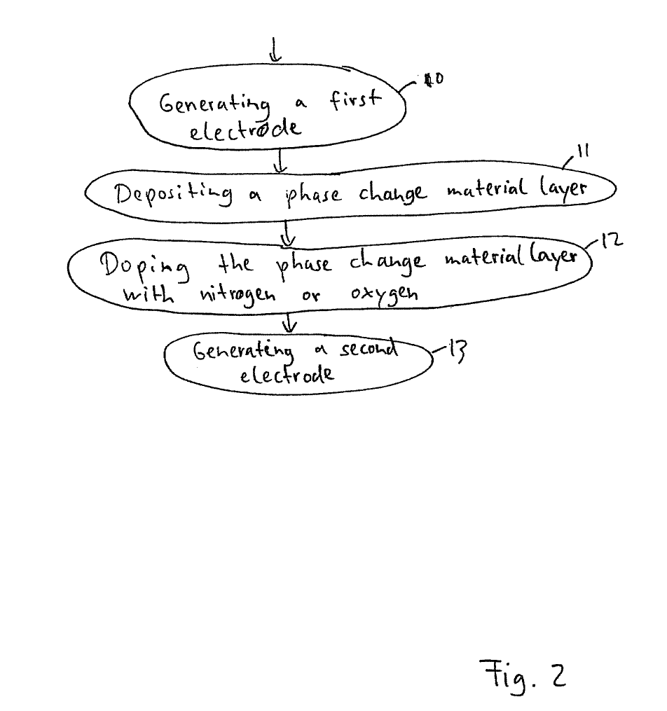

When producing the phase change memory cell 1 advantageously—as is shown in the diagram of FIG. 2 in a purely schematic way—in a step 10 first the above first electrode 4 may be generated. Then—according to the step 11 shown in FIG. 2—the phase change material layer 2 with the above switching active material compound with the chemical composition GaₓGe_{y}In_{z}Sb_{1-x-y-z} may be deposited, and then—according to the step 12 shown in FIG. 2—the phase change material layer 2 may be doped with nitrogen or oxygen, and finally—according to the step 13 shown in FIG. 2—the above second electrode 3 may be generated.

According to another embodiment of the inventive phase change memory, the ternary material compounds GaSb—N or GaSb—O are used as active phase change material in the electrical phase change memory cell. These compounds offer, vis-à-vis the hitherto used standard materials, the possibility of a simultaneous improvement of the characteristics of the phase change memory both with respect to the power requirement (in particular for the RESET step or deleting process, respectively) and the writing rate (SET step or writing process, respectively), and with respect to the data storage at increased temperatures.

1. A method of manufacturing at least one resistively switching memory, the method comprising:
generating a first electrode;
depositing a phase change material layer, the phase change material layer comprising a composition of formula GaₓGe_{y}In_{z}Sb_{1-x-y-z} that also incorporates at least elemental oxygen or elemental nitrogen, where:
x, y, and z are each between 0 and 1;
any one or any two of x, y, and z may be 0;
the sum of x, y, and z is less than or equal to 1; and
generating a second electrode, the phase change material layer in working relation with the first electrode and with the second electrode.

2. The method of claim 1 wherein depositing the phase change material layer comprises depositing the phase change material layer in the presence of a reactive gas that effects doping of the composition of formula GaₓGe_{y}In_{z}Sb_{1-x-y-z}.

3. The method of claim 2 wherein the reactive gas comprises nitrogen or oxygen.

4. The method of claim 2 wherein the reactive gas comprises oxygen and is free of nitrogen.

5. The method of claim 2 wherein the reactive gas comprises nitrogen and oxygen.

6. The method of claim 2 wherein the reactive gas comprises nitrogen (N₂) gas or oxygen (O₂) gas.

7. The method of claim 2 where the reactive gas comprises N₂, O₂, NH₃, H₂O, N₂O, NO, CO, CO₂, NO₂, O₃, or a mixture of any of these gases.

8. The method of claim 2, the method further comprising adjusting the concentration of the reactive gas to control the level of doping in the composition of formula GaₓGe_{y}In_{z}Sb_{1-x-y-z} or effect varying levels of doping in different portions of the composition of formula GaₓGe_{y}In_{z}Sb_{1-x-y-z}.

9. The method of claim 2, the method further comprising adjusting the reactive gas environment to continuously vary the level of doping within the phase change material layer.

10. The method of claim 1 wherein depositing the phase change material layer is accomplished via reactive magnetron sputtering employing an inert sputtering gas, via a chemical vapor deposition process, via a plasma-enhanced chemical vapor deposition process, or via a metal-organic chemical vapor deposition process.

11. The method of claim 1 wherein depositing the phase change material layer comprises:
nitriding the phase change material layer during the deposition process to generate a composition of formula GaₓGe_{y}In_{z}Sb_{1-x-y-z}:N in the phase change material layer, or
oxidizing the phase change material layer during the deposition process to generate a composition of formula GaₓGe_{y}In_{z}Sb_{1-x-y-z}:O in the phase change material layer.

12. The method of claim 1 wherein depositing the phase change material layer comprises nitriding and oxidizing the phase change material layer during the deposition process to generate a composition of formula GaₓGe_{y}In_{z}Sb_{1-x-y-z}:N:O in the phase change material layer.

13. The method of claim 1 wherein depositing the phase change material layer is accomplished via a sputtering process or a co-sputtering process.

14. The method of claim 13 wherein a compound of formula GaₓSb₁₋ₓ is employed as a target of the sputtering process.

15. The method of claim 13, the method further comprising employing Antimony or a compound that includes Antimony as a target of the co-sputtering process and wherein depositing the phase change material layer comprises:
oxidizing the phase change material layer during the deposition process to generate a compound with the chemical composition (Ga,Ge)In:Sb:O in the phase change material layer, or
nitriding the phase change material layer during the deposition process to generate a compound with the chemical composition (Ga,Ge)In:Sb:N in the phase change material layer.

16. The method of claim 13, the method further comprising;
employing a compound of formula GaN and a compound of formula GaₓSb₁₋ₓ, as two co-targets of the co-sputtering process,
employing the element Sb and a compound of formula Ga_{0.5}Sb_{0.5} as two co-targets of the co-sputtering process,
employing the element Sb and a compound of formula GaN as two co-targets of the co-sputtering process,
employing a compound of formula GaN and a compound of formula SbN as two co-targets of the co-sputtering process, or
employing a compound of formula GaSb and a compound of formula Sb—N as two co-targets of the co-sputtering process.

17. The method of claim 13 wherein a compound of formula (Ga_{y}Sb_{1-y})_{z}N_{1-z} is generated in the phase change material layer during the co-sputtering process.

18. The method of claim 13, the method further comprising employing a composition of formula GaₓSb₁₋ₓ as a base target, SiO₂, as an oxidation target, and AgN or Si₃N₄ as a nitriding target during the co-sputtering process.

19. The method of claim 13, the method further comprising employing SiO₂ or Si₃N₄ as a dielectric material during the co-sputtering process and high-frequency (RF) sputtering as the co-sputtering process.

20. The method of claim 1 wherein the phase change material layer further comprises GaSb—N, GaSb—O, or a combination of these.

21. The method of claim 1 wherein the phase change material layer comprising a composition of formula GaₓGe_{y}In_{z}Sb_{1-x-y-z} also incorporates elemental oxygen.

22. The method of claim 21 wherein the phase change material layer comprising a composition of formula GaₓGe_{y}In_{z}Sb_{1-x-y-z} is free of nitrogen.

23. A method of manufacturing at least one resistively switching memory, the method comprising:
generating a first electrode;
generating a second electrode; and
depositing a resistively switching material layer so a doping concentration of the resistively switching material layer is, starting out from a boundary region between the first electrode and the resistively switching material layer, continuously reduced towards a center of the resistively switching material layer and is subsequently increased again towards a boundary region between the resistively switching material layer and the second electrode.

24. The method of claim 23 wherein depositing the resistively switching material comprises depositing the resistively switching material in the presence of a reactive gas that effects doping of at least some of the resistively switching material.

25. The method of claim 24 wherein the reactive gas comprises nitrogen or oxygen.

26. The method of claim 24 wherein the reactive gas comprises oxygen and is free of nitrogen.

27. The method of claim 23 wherein depositing the resistively switching material is accomplished via a sputtering process or a co-sputtering process.

28. The method of claim 27 wherein a compound of formula (Ga_{y}Sb_{1-y})_{z}N_{1-z} is generated in the phase change material layer during the co-sputtering process, where:
x, y, and z are each between 0 and 1;
any one or any two of x, y, and z may be 0; and
the sum of x, y, and z is less than or equal to 1.

29. The method of claim 27 wherein a compound of formula GaₓSb₁₋ₓ is employed as a target of the sputtering process, where: x may be 0, 1, or between 0 and 1.
